(19) United States
(12) Patent Application Publication
(10) Pub. No.: US 2022/0159875 A1
(43) Pub. Date: May 19, 2022

(54) PRESSURE CONTROL FOR THERMAL MANAGEMENT SYSTEM

(71) Applicant: 3M INNOVATIVE PROPERTIES COMPANY, St. Paul, MN (US)

(72) Inventor: Phillip E. Tuma, Faribault, MN (US)

(21) Appl. No.: 17/431,665

(22) PCT Filed: Feb. 12, 2020
(86) PCT No.: PCT/IB2020/051152

§ 371 Date: Aug. 17, 2021

Related U.S. Application Data
(60) Provisional application No. 62/806,963, filed on Feb. 18, 2019.

(51) Int. Cl. H05K 7/20

(52) U.S. Cl. CPC H05K 7/20327; H05K 7/203; H05K 7/20818

(57) ABSTRACT

A thermal management system includes a housing having an interior space; a heat-generating component disposed within the interior space; and a working fluid comprising a halogenated material disposed within the interior space such that the heat-generating component contacts a liquid phase of the working fluid. The system further includes a bellows assembly disposed with the interior space, the bellows assembly comprising a first bellows and a second bellows. The first bellows is in fluid communication with the interior space and the second bellows is in fluid communication with an environment external to the housing. The first and second bellows are mechanically coupled such that expansion of the first bellows causes contraction of the second bellows, and contraction of the first bellows causes expansion of the second bellows.

### FIELD

The present disclosure relates to compositions useful for immersion cooling systems.

### BACKGROUND

Various systems for managing the pressure of fluid in immersion cooling systems are described in, for example, U.S. Pat. App. Pubs. 2015/0060009 and 2014/0216686.

### SUMMARY

In some embodiments, a thermal management system is provided. The system includes a housing having an interior space; a heat-generating component disposed within the interior space; and a working fluid comprising a halogenated material disposed within the interior space such that the heat-generating component contacts a liquid phase of the working fluid. The system further includes a bellows assembly disposed with the interior space, the bellows assembly comprising a first bellows and a second bellows. The first bellows is in fluid communication with the interior space and the second bellows is in fluid communication with an environment external to the housing. The first and second bellows are mechanically coupled such that expansion of the first bellows causes contraction of the second bellows, and contraction of the first bellows causes expansion of the second bellows.

The above summary of the present disclosure is not intended to describe each embodiment of the present disclosure. The details of one or more embodiments of the disclosure are also set forth in the description below. Other features, objects, and advantages of the disclosure will be apparent from the description and from the claims.

### DETAILED DESCRIPTION

Large scale computer server systems can perform significant workloads and generate a large amount of heat during their operation. A significant portion of the heat is generated by the operation of these server systems. Due in part to the large amount of heat generated, these servers are typically rack mounted and air-cooled via internal fans and/or fans attached to the back of the rack or elsewhere within the server ecosystem. As the need for access to greater and greater processing and storage resources continues to expand, the density of server systems (i.e., the amount of processing power and/or storage placed on a single server, the number of servers placed in a single rack, and/or the number of servers and or racks deployed on a single server farm), continue to increase. With the desire for increasing processing or storage density in these server systems, the thermal challenges that result remain a significant obstacle. Conventional cooling systems (e.g., fan based) require large amounts of power, and the cost of power required to drive such systems increases exponentially with the increase in server densities. Consequently, there exists a need for efficient, low power usage system for cooling the servers, while allowing for the desired increased processing and/or storage densities of the server systems.

Two-phase immersion cooling is an emerging thermal management technology for the high-performance server computing market which relies on the heat absorbed in the process of vaporizing a liquid (the cooling fluid) to a create a vapor (i.e., the heat of vaporization). The working fluids used in this application must meet certain requirements to be viable in the application. For example, the boiling temperature during operation should be in a range between for example 30° C.-75° C. Generally, this range accommodates maintaining the server components at a sufficiently cool temperature while allowing heat to be dissipated efficiently to an ultimate heat sink (e.g., outside air). The working fluid must be inert so that it is compatible with the materials of construction and the electrical components. Certain perfluorinated and partially fluorinated materials meet these requirements.

In a typical two-phase immersion cooling system, servers are at least partially submerged in a bath of working fluid (having a boiling temperature T_{b}) that is sealed and maintained at or near atmospheric pressure. A vapor condenser integrated into the tank is cooled by water at temperature T_{w}. During operation, after steady reflux is established, the working fluid vapor generated by the boiling working fluid forms a discrete vapor level as it is condensed back into the liquid state by the condenser. Above this layer is the “headspace,” a mixture of a non-condensable gas (typically air), water vapor, and the working fluid vapor. These 3 distinct phases (liquid, vapor, and headspace) occupy volumes within the tank.

Traditionally, immersion cooling systems were built as pressure vessels (i.e., to operate at greater than atmospheric pressure). Pressure vessels are undesirable at least because they are heavier, more difficult to service and seal, and result in appreciable working fluid loss. Consequently, immersion cooling systems that operate at atmospheric pressure are desirable. Such immersion cooling systems have been developed and include a bellows mounted above and external to the tank but in fluid communication with the interior of the tank. While effective in maintaining atmospheric pressure (or at least significantly reducing pressure within the tank), such placement of the bellows meaningfully increases the overall footprint/size of the immersion system and/or renders substantial portions of the immersion systems unavailable for input/output penetrations. Consequently, immersion cooling systems that can space efficiently house bellows within lower regions of the tank while maintaining the interior of the tank at or near atmospheric pressure are desirable.

Maintaining the headspace phase in the tank is desirable because it enables access to the tank while it is operational and the fluid within is boiling. Specifically, with a headspace phase present, the top of the tank can be opened to permit servicing some portion of the computer hardware within, without appreciable fluid loss. However, during normal operation (tank sealed), the non-condensable gases (e.g., air) present within the headspace can be entrained into the vapor phase and degrade the condensation performance of the condenser. This can be prevented by modulating the condenser capacity such that the vapor rises far above the condenser, effectively removing the headspace and eliminating its deleterious effect on condenser performance. Doing this, however, makes fluid losses during servicing unacceptable. Therefore, immersion cooling systems that can accommodate sequestration of the headspace when it is not needed and restoring it automatically for servicing operations may be desirable.

As used herein, “fluoro-” (for example, in reference to a group or moiety, such as in the case of “fluoroalkylene” or “fluoroalkyl” or “fluorocarbon”) or “fluorinated” means (i) partially fluorinated such that there is at least one carbon-bonded hydrogen atom, or (ii) perfluorinated.

As used herein, “perfluoro-” (for example, in reference to a group or moiety, such as in the case of “perfluoroalkylene” or “perfluoroalkyl” or “perfluorocarbon”) or “perfluorinated” means completely fluorinated such that, except as may be otherwise indicated, any carbon-bonded hydrogens are replaced by fluorine atoms.

As used herein, the singular forms “a”, “an”, and “the” include plural referents unless the content clearly dictates otherwise. As used in this specification and the appended embodiments, the term “or” is generally employed in its sense including “and/or” unless the content clearly dictates otherwise.

As used herein, the recitation of numerical ranges by endpoints includes all numbers subsumed within that range (e.g. 1 to 5 includes 1, 1.5, 2, 2.75, 3, 3.8, 4, and 5).

Unless otherwise indicated, all numbers expressing quantities or ingredients, measurement of properties and so forth used in the specification and embodiments are to be understood as being modified in all instances by the term “about.” Accordingly, unless indicated to the contrary, the numerical parameters set forth in the foregoing specification and attached listing of embodiments can vary depending upon the desired properties sought to be obtained by those skilled in the art utilizing the teachings of the present disclosure. At the very least, and not as an attempt to limit the application of the doctrine of equivalents to the scope of the claimed embodiments, each numerical parameter should at least be construed in light of the number of reported significant digits and by applying ordinary rounding techniques.

Generally, the present disclosure is directed to a thermal management system for a heat generating component (e.g., a server computer) that allows for atmospheric pressure conditions to be maintained within the system and include one or more bellows within the system housing. In some embodiments, the thermal management system may operate as two-phase vaporization-condensation systems for cooling one or more heat generating components.

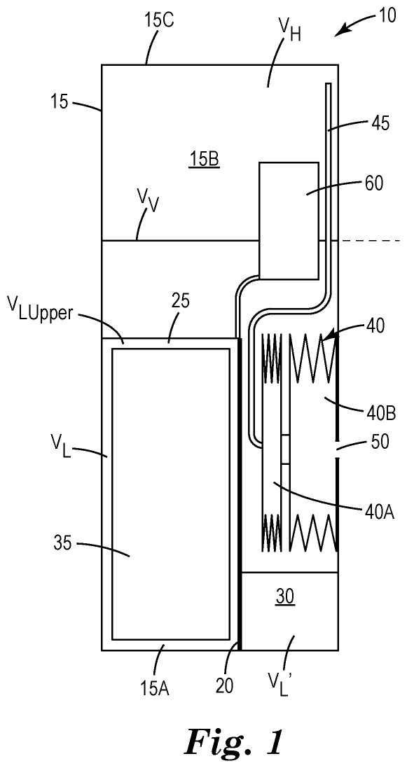

FIG. 1 provides a schematic illustration of a thermal management system 10 in accordance with some embodiments of the present disclosure, operating at a steady state. As shown in FIG. 1, in some embodiments, the thermal management system 10 may include a housing 15 having an interior space. The housing 15 may be a sealed housing (e.g., hermetically sealed). A partition 20 within the interior space may define a first liquid chamber 25 and a second liquid chamber 30 within the interior space of the housing 15. The second liquid chamber 30 may be considered an “overflow” chamber that allows for precise control of the maximum fluid height in the first liquid chamber 25.

Within the first liquid chamber 25, a liquid phase V_{L} of a working fluid having an upper liquid surface V_{L upper} (i.e., the topmost level of the liquid phase V_{L}) may be disposed. The interior space may also include an upper volume 15B extending from the liquid surface 20 to an upper wall 15C of the housing 15.

In some embodiments, a heat generating component 35 may be disposed within the interior space such that it is at least partially immersed (and up to fully immersed) in the liquid phase V_{L} of the working fluid. While heat generating component 35 is illustrated as being totally submerged below the upper liquid surface V_{L upper}, in some embodiments, the heat generating component 35 may be only partially submerged. In some embodiments, the heat generating component 35 may include (or be) one or more electronic devices, such as computing servers.

During steady state operation of the system 10, the upper volume 15B may include a vapor phase V_{V} (generated by the boiling working fluid and forming a discrete phase as it is condensed back into the liquid state) and a headspace phase V_{H} disposed above the vapor phase V_{V}. The headspace phase V_{H} may include a mixture of a non-condensable gas (e.g., air), water vapor, and the working fluid vapor.

In some embodiments, the system 10 may further include a bellows assembly 40 disposed within the housing 15. For example, as shown in FIG. 1, a bellows assembly 40 that includes a first bellows 40A and a second bellows 40B may be disposed within the second liquid chamber 30. It is to be appreciated, however, that the bellows assembly 40 may be positioned anywhere within the housing such that, during steady state operation, it is predominantly in the vapor phase V_{V} (e.g., at least 50%, at least 80%, or at least 90%, based on the total size of the bellows assembly). In some embodiments, the bellows assembly may be disposed entirely within the vapor phase V_{V} or partially within the vapor phase V_{V} (such that it is partially within the liquid phase V_{L})

In some embodiments, the first bellows 40A and second bellows 40B may be mechanically coupled. Specifically, in some embodiments, the first and second bellows 40A/40B may be mechanically coupled such that expansion in one of the bellows causes contraction in the other, and contraction of one of the bellows causes expansion of the other. In some embodiments, the first bellows 40A and second bellows 40B may not be in fluid communication with one another.

In some embodiments, the first bellows 40A may be in fluid communication with the headspace phase V_{H} (e.g., via a fluid conduit 45). In some embodiments, the second bellows 40B may be in fluid communication with an area external to the housing 15 (i.e., vented to the atmosphere) via a vent port 50 disposed within, for example, a sidewall of the housing 15.

In various embodiments, a heat exchanger 60 (e.g., a condenser) may be disposed within the upper volume 15B. Generally, the heat exchanger 60 may be configured such that it is able to condense the vapor phase V_{V} of the working fluid that is generated as a result of the heat that is produced by the heat generating element 35. For example, the heat exchanger 30 may have an external surface that is maintained at a temperature that is lower than the condensation temperature of the vapor phase V_{V} of the working fluid. In this regard, at the heat exchanger 30, a rising vapor phase V_{V} of the working fluid may be condensed back to liquid phase or condensate by releasing latent heat to the heat exchanger 30 as the rising vapor phase V_{V} comes into contact with the heat exchanger 30. The resulting condensate may then be returned back to the liquid phase VL disposed in the lower volume of 15 A.

In some embodiments, the working fluid may be or include one or more halogenated fluids (e.g., fluorinated or chlorinated). For example, the working fluid may be a fluorinated organic fluid. Suitable fluorinated organic fluids may include hydrofluoroethers, fluoroketones (or perfluoroketones), hydrofluoroolefins, perfluorocarbons (e.g., perfluorohexane), perfluoromethyl morpholine, or combinations thereof.

In some embodiments, in addition to the halogenated fluids, the working fluids may include (individually or in any combination): ethers, alkanes, perfluoroalkenes, alkenes, haloalkenes, perfluorocarbons, perfluorinated tertiary amines, perfluoroethers, cycloalkanes, esters, perfluoroketones, ketones, oxiranes, aromatics, siloxanes, hydrochlorocarbons, hydrochlorofluorocarbons, hydrofluorocarbons, hydrofluoroolefins, hydrochloroolefins, hydrochlorofluoroolefins, hydrofluoroethers, or mixtures thereof based on the total weight of the working fluid; or alkanes, perfluoroalkenes, haloalkenes, perfluorocarbons, perfluorinated tertiary amines, perfluoroethers, cycloalkanes, perfluoroketones, aromatics, siloxanes, hydrochlorocarbons, hydrochlorofluorocarbons, hydrofluorocarbons, hydrofluoroolefins, hydrochlorofluoroolefins, hydrofluoroethers, or mixtures thereof, based on the total weight of the working fluid. Such additional components can be chosen to modify or enhance the properties of a composition for a particular use.

In some embodiments, the working fluids of the present disclosure may have a boiling point during operation (e.g., pressures of between 0.9 atm and 1.1 atm or 0.5 atm and 1.5 atm) of between 30-75° C., or 35-75° C., 40-75° C., or 45-75° C. In some embodiments, the working fluids of the present invention may have a boiling point during operation of greater than 40° C., or greater than 50° C., or greater than 60° C., greater than 70° C., or greater than 75° C.

In some embodiments, the working fluids of the present disclosure may have dielectric constants that are less than 4.0, less than 3.2, less than 2.3, less than 2.2, less than 2.1, less than 2.0, or less than 1.9, as measured in accordance with ASTM D150 at room temperature.

In some embodiments, the working fluids of the present disclosure may be hydrophobic, relatively chemically unreactive, and thermally stable. The working fluids may have a low environmental impact. In this regard, the working fluids of the present disclosure may have a zero, or near zero, ozone depletion potential (ODP) and a global warming potential (GWP, 100 yr ITH) of less than 500, 300, 200, 100 or less than 10.

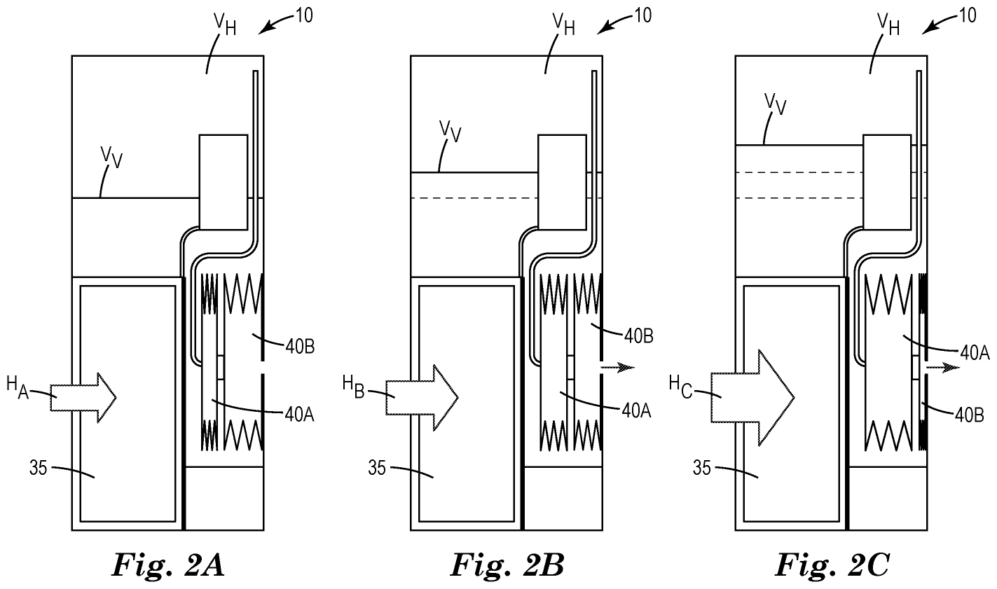

Referring now to FIGS. 2A-2C, steady state operation (or near steady state operation) of the thermal management system 10, according to some embodiments, is depicted. It should be noted that the arrows H_{A}, H_{B}, and H_{C} are of varying sizes and represent the relative amount of power being consumed by the heat generating component 35 (the larger the arrow, the more heat being generated). In FIG. 2A, a relatively low amount of power is being consumed by the heat generating component 35, the first bellows 40A is in a fully compressed state and the second bellows 40B is in a fully expanded state. As the power increases in FIG. 2B, the level of the vapor phase V_{V} will rise in the tank as it must to find additional surface area for condensation. This results in a slight rise in the pressure within the tank. This pressure rise causes the second bellows 40B (in fluid communication with the external environment) to contract slightly. It in turn pulls on first bellows 40A causing first bellows 40A to expand. As a result of the fluid communication between the headspace phase V_{H} and the first bellows 40A, a portion of the headspace phase VH is drawn into the first bellows 40A. In FIG. 2C, the power consumption is increased further, causing additional contraction of second bellows 40B, additional expansion of first bellows 40A, and sequestration of additional headspace phase VH, within first bellows 40A.

### Listing of Embodiments

1. A thermal management system comprising:

a housing having an interior space;

a heat-generating component disposed within the interior space; and

a working fluid comprising a halogenated material disposed within the interior space such that the heat-generating component contacts a liquid phase of the working fluid;

a bellows assembly disposed with the interior space, the bellows assembly comprising a first bellows and a second bellows, wherein the first bellows is in fluid communication with the interior space and the second bellows is in fluid communication with an environment external to the housing; and

wherein the first and second bellows are mechanically coupled such that expansion of the first bellows causes contraction of the second bellows, and contraction of the first bellows causes expansion of the second bellows.
2. The thermal management system of embodiment 1, wherein the thermal management system is configured such that in a steady state operating condition, (i) a liquid phase of the working fluid is disposed in a lower volume of the housing, (ii) a vapor phase of the working fluid is disposed above liquid phase, and (iii) a headspace phase comprising a non-condensable gas, water vapor, and vapor of the working fluid is disposed above the vapor phase.
3. The thermal management system of embodiment 2, wherein the first bellows is in fluid communication with the headspace phase.
4. The thermal management system of any one of the previous embodiments, wherein the environment external to the housing is at atmospheric pressure.
5. The thermal management system of any one of the previous embodiments, further comprising a heat exchanger disposed within the interior space such that upon vaporization of the liquid phase, the vapor phase contacts the heat exchanger.
6. The thermal management system of any one of the previous embodiments, wherein the working fluid comprises a fluorinated material.
7. The thermal management system of any one of the previous embodiments, wherein the working fluid has a boiling point at 1 atm of between 30 and 75° C.
8. The thermal management system of any one of the previous embodiments, wherein the working fluid has a dielectric constant of less than 2.5.
9. The thermal management system of any one of the previous embodiments, wherein the heat-generating component comprises an electronic device.
10. The thermal management system of embodiment 9, wherein the electronic device comprises a computing server.
11. The thermal management system of embodiment 10, wherein the computing server operates at frequency of greater than 3 GHz.

Although specific embodiments have been illustrated and described herein for purposes of description of some embodiments, it will be appreciated by those of ordinary skill in the art that a wide variety of alternate and/or equivalent implementations may be substituted for the specific embodiments shown and described without departing from the scope of the present disclosure.

What is claimed is:

1. A thermal management system comprising:
a housing having an interior space;
a heat-generating component disposed within the interior space; and
a working fluid comprising a halogenated material disposed within the interior space such that the heat-generating component contacts a liquid phase of the working fluid;
a bellows assembly disposed with the interior space, the bellows assembly comprising a first bellows and a second bellows, wherein the first bellows is in fluid communication with the interior space and the second bellows is in fluid communication with an environment external to the housing; and
wherein the first and second bellows are mechanically coupled such that expansion of the first bellows causes contraction of the second bellows, and contraction of the first bellows causes expansion of the second bellows.

2. The thermal management system of claim 1, wherein the thermal management system is configured such that in a steady state operating condition, (i) a liquid phase of the working fluid is disposed in a lower volume of the housing, (ii) a vapor phase of the working fluid is disposed above liquid phase, and (iii) a headspace phase comprising a non-condensable gas, water vapor, and vapor of the working fluid is disposed above the vapor phase.

3. The thermal management system of claim 2, wherein the first bellows is in fluid communication with the headspace phase.

4. The thermal management system of claim 1, wherein the environment external to the housing is at atmospheric pressure.

5. The thermal management system of claim 1, further comprising a heat exchanger disposed within the interior space such that upon vaporization of the liquid phase, the vapor phase contacts the heat exchanger.

6. The thermal management system of claim 1, wherein the working fluid comprises a fluorinated material.

7. The thermal management system of claim 1, wherein the working fluid has a boiling point at 1 atm of between 30 and 75° C.

8. The thermal management system of claim 1, wherein the working fluid has a dielectric constant of less than 2.5.

9. The thermal management system of claim 1, wherein the heat-generating component comprises an electronic device.

10. The thermal management system of claim 9, wherein the electronic device comprises a computing server.

11. The thermal management system of claim 10, wherein the computing server operates at frequency of greater than 3 GHz.
